(19) United States
(12) Patent Application Publication
(10) Pub. No.: US 2025/0107124 A1
(43) Pub. Date: Mar. 27, 2025

(54) Power Semiconductor Device Having Shaped Trench Ends

(71) Applicant: Wolfspeed, Inc., Durham, NC (US)

(72) Inventors: Woongsun Kim, Cary, NC (US); S M Naeemul Islam, Morrisville, NC (US); Madankumar Sampath, Durham, NC (US); Sei-Hyung Ryu, Cary, NC (US)

(21) Appl. No.: 18/475,298

(22) Filed: Sep. 27, 2023

(51) Int. Cl. H01L 29/739; H01L 29/06; H01L 29/16; H01L 29/423

(52) U.S. Cl. CPC H10D 12/481; H10D 62/127; H10D 62/8325; H10D 64/513

(57) ABSTRACT

Semiconductor devices are provided. In one example, a semiconductor device includes a semiconductor structure. The semiconductor device includes a gate finger in a gate trench in the semiconductor structure. The gate trench extends a length in the semiconductor structure. The gate trench has a first portion having a first width and a second portion having a second width. The second width is different than the first width.

### FIELD

The present disclosure relates generally to semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or Group III nitride-based semiconductor materials.

### SUMMARY

Aspects and advantages of embodiments of the present disclosure will be set forth in part in the following description, or may be learned from the description, or may be learned through practice of the embodiments.

One example aspect of the present disclosure is directed to a semiconductor device. The semiconductor device includes a semiconductor structure. The semiconductor device includes a gate finger in a gate trench in the semiconductor structure. The gate trench extends a length in the semiconductor structure. The gate trench has a first portion having a first width and a second portion having a second width. The second width is different than the first width.

Another example aspect of the present disclosure is directed to a semiconductor device. The semiconductor device includes a semiconductor structure comprising an active region and an inactive region. The semiconductor device includes a gate bus on the inactive region. The semiconductor device includes a gate trench having a first portion in the active region and a second portion in the inactive region. The semiconductor device includes a gate finger extending in the active region in the first portion of the gate trench. The semiconductor device includes a field insulating layer on the inactive region and in the second portion of the gate trench.

Another example aspect of the present disclosure is directed to a semiconductor device. The semiconductor device includes a wide bandgap semiconductor structure having an active region and an inactive region. The active region has one or more unit cells. The semiconductor device includes a gate bus. The semiconductor device includes a gate trench in the wide bandgap semiconductor structure. The gate trench has a first portion and a second portion. The semiconductor device includes a gate finger in the gate trench. The semiconductor device includes a field insulating layer in the second portion of the gate trench. The gate finger overlaps the gate bus at the second portion of the gate trench. The first portion of the gate trench has a first width and the second portion of the gate trench has a second width. The second width is different than the first width.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a plan view of a semiconductor wafer that includes a plurality of semiconductor devices according to example embodiments of the present disclosure.

FIG. 2A depicts a plan view of one of the semiconductor devices included on the semiconductor wafer of FIG. 1 according to example embodiments of the present disclosure.

FIG. 2B depicts a plan view of the semiconductor device of FIG. 2A according to example embodiments of the present disclosure with the source pad and gate pad metallization removed.

FIG. 2C depicts a schematic cross-sectional diagram of an example unit cell structure in an active region of the device according to example embodiments of the present disclosure.

FIG. 3 depicts a plan view of a portion of an example gate trench according to example embodiments of the present disclosure.

FIG. 4A depicts a plan view of a portion of an example interface between a gate finger and a gate bus according to example embodiments of the present disclosure.

FIG. 4B depicts a cross-sectional view of the example interface of FIG. 4A along the line A-A′ according to example embodiments of the present disclosure.

FIG. 4C depicts a cross-sectional view of the example intersection of FIG. 4A along the line B-B′ according to example embodiments of the present disclosure.

FIG. 5 depicts a plan view of a portion of an example gate trench according to example embodiments of the present disclosure.

FIG. 6 depicts a view of contiguous gate trenches according to example embodiments of the present disclosure.

FIGS. 7A, 7B, and 7C depict views of portions of example gate trenches according to example embodiments of the present disclosure.

FIG. 8 depicts a cross-sectional view of an example intersection between a gate finger and a gate bus according to example embodiments of the present disclosure.

FIG. 9 depicts a cross-sectional view of an example intersection between a gate finger and a gate bus according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

A power semiconductor device may have a semiconductor substrate, such as a silicon carbide substrate having a first conductivity type (e.g., an n-type substrate), on which an epitaxial layer structure having the first conductivity type (e.g., n-type) is formed. A portion of this epitaxial layer structure (which may include one or more separate layers) functions as a drift region of the power semiconductor device. The device typically includes an “active region,” which includes one or more unit cell structures that have a junction such as a p-n junction. The active region may be formed on and/or in the drift region. The active region acts as a main junction for blocking voltage in the reverse bias direction and providing current flow in the forward bias direction. The power semiconductor devices may have a unit cell structure in which the active region of each power semiconductor device includes a plurality of individual unit cell structures that are electrically connected in parallel and that together function as a single power semiconductor device.

Power semiconductor devices are often fabricated from wide bandgap semiconductor materials, such as silicon carbide or Group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that the power semiconductor devices according to example embodiments of the present disclosure may be used with any semiconductor material, such as other wide bandgap semiconductor materials, without deviating from the scope of the present disclosure. Example wide bandgap semiconductor materials include silicon carbide (e.g., 2.996 eV band gap for alpha silicon carbide at room temperature) and the Group III-nitrides (e.g., 3.36 eV band gap for gallium nitride at room temperature).

Power semiconductor devices can have a lateral structure or a vertical structure. In a device having a lateral structure, the terminals of the device (e.g., the drain, gate and source terminals for a power MOSFET device) are on the same major surface (e.g., top surface or bottom surface) of a semiconductor structure. In contrast, in a power semiconductor device having a vertical structure, at least one terminal is provided on each major surface of the semiconductor structure. For instance, in a vertical MOSFET device, the source may be on the top surface of the semiconductor structure and the drain may be on the bottom surface of the semiconductor structure, or vice versa. Herein, the term “semiconductor structure” refers to a structure that includes one or more semiconductor layers, such as semiconductor substrates and/or semiconductor epitaxial layers.

One approach to form such devices involves forming a plurality of “unit cell” structures, where each unit cell structure includes a transistor. In high power applications, a large number of these unit cells (e.g., hundreds or thousands) are typically provided on a single semiconductor substrate, and a gate electrode is formed on a top side of the semiconductor substrate that acts as the gate electrode for all of the unit cells. The opposite (bottom) side of the semiconductor substrate acts as a common drain for all of the unit cells of the device. A plurality of source contacts are formed on source regions in the semiconductor layer structure. In some embodiments, the source regions may be exposed within openings in the gate electrode. These source contacts are also electrically connected to each other to serve as a common source. The resulting device has three terminals, namely a common source terminal, a common drain terminal, and a common gate electrode that act as the terminals for the hundreds or thousands of individual unit cell transistors. It will be appreciated that the above description is of an n-type MOSFET; the locations of the drain and source, as well as the conductivity types of the various layers/regions, would be reversed for a p-type MOSFET.

The gate structure (e.g., gate electrode pattern) of a power MOSFET may be implemented by forming a patterned conductive layer on the semiconductor structure. The patterned conductive layer may include, for instance, a gate pad, one or more gate buses, and a plurality of elongated gate fingers that extend through an active region of the device. In some examples, the patterned conductive layer may include a semiconductor layer such as, for example, a polysilicon layer. The gate pad may be in an inactive region of the device, and each gate finger may connect to the gate pad, either directly or via one or more of the gate bus(s).

According to example aspects of the present disclosure, the gate pad portion of the gate structure may be formed on a thick field insulating layer (e.g., field oxide layer). The field insulating layer may include, for example, a silicon oxide layer, although other insulating materials or a combination of insulating materials may be used. A metal gate bond pad may be formed on top of a portion of the gate pad and may form an ohmic contact to the gate pad. Bond wires may be attached to the gate bond pad to provide a mechanism for applying a bias voltage to the gate structure of the device.

As discussed above, the gate structure and the metal layers/bond pads for the source, gate and drain are formed on a semiconductor structure. The semiconductor structure has an active region in which the unit cell transistors are formed and an inactive region. The inactive region may include a gate pad portion that is underneath the above-discussed gate bond pad and field insulating layer, a gate bus portion that is underneath the above-discussed gate buses and field insulating layer, and a termination portion (e.g., edge termination portion) that may surround the active region.

During operation, the MOSFET may switch from reverse blocking state (where the device may block a very large voltage and not conduct current) to the on-state (where the device may conduct large currents) in a very short period of time. As the device switches states, a displacement current is generated that flows between the drain terminal on the bottom surface of the device and the source terminal on the upper surface of the device (in an n-type device). When the displacement current flows, a voltage is generated in the implanted region of the semiconductor structure. Pursuant to Ohm's law, a value of this voltage is equal to the product of the displacement current and the resistance of the semiconductor structure along the displacement current path. In silicon carbide-based semiconductor structures, implanted regions tend to have high sheet resistance. In the portion of the inactive region beneath the gate structure, the resistance may be high due to the implanted region underneath the field insulating layer and the capacitance of the p-n junction may be high for the reasons discussed above. As such, the displacement current flowing in the portion of the inactive region beneath the gate structure may generate high voltages in the semiconductor structure during device operation. If the generated voltage is sufficiently high, it may exceed the breakdown voltage of the insulating layers, which may damage the device.

Typically, a thin gate oxide layer may be provided between the gate fingers and the implanted region of the semiconductor layer structure. This gate oxide layer may include, for example, a silicon oxide pattern, although other insulating materials may be used. The gate oxide pattern may be between the source contacts and the field insulating layer, and hence the displacement current generated in the portion of the inactive region beneath the gate structure may flow underneath the gate oxide pattern. This gate oxide layer may be much thinner than the field insulating layer, having a thickness of, for example, between about 30 to about 50 nanometers. For silicon oxide, the breakdown voltage may be about 12 MV/cm multiplied by the thickness of the oxide. Thus, the breakdown voltage for a 600 nanometer thick silicon oxide field insulating layer would be about 720 Volts.

However, including both a gate oxide layer and a field insulating layer presents challenges. For instance, in some embodiments, the field insulating layer may be provided in a gate trench near the termination of a gate finger, where the finger intersects a gate bus. It is beneficial to form a strong electrical contact between the gate finger and the gate bus. However, because the field insulating layer is relatively thick, and occupies a substantial portion of the gate trench, the surface area available for contact between the gate finger and the gate bus must compete with the thickness of the field insulating layer in the limited space available in the gate trench.

Example aspects of the present disclosure provide for gate trenches having a first portion and a second portion each extending along a length. The first portion of the gate trench may be in the active region of a power semiconductor device, where the unit cell transistor devices are located. The second portion of the gate trench may be in the inactive region, where the gate finger intersects with the gate bus. The first portion and the second portion can have different widths.

In some examples, the second portion can have a greater width than the first portion. The greater width of the second portion can provide for including the field insulating layer along with the gate oxide layer in the gate trench while maintaining solid electrical contact between the gate finger and the gate bus. In some examples, a wider trench may allow for deposition of a field insulating layer (e.g., using a deposition process, such as a PECVD process) with a thicker sidewall in the trench relative to narrower trench widths. This may allow for a thicker field insulating layer in the gate trench, increasing reliability of the device, for instance, by improving time-dependent dielectric breakdown (TDDB). Alternatively, in some examples, the second portion can have a width that is less than the first portion.

Example aspects of the present disclosure provide for gate trenches having a first portion and a second portion each extending along a length. The first portion of the gate trench may be in the active region of a power semiconductor device, where the unit cell structures are located. The second portion of the gate trench may be in the inactive region, where the gate finger intersects with the gate bus. The first portion and the second portion can have different shapes. For instance, the first portion of the gate trench may be a shape having generally constant width along its length. For instance, the width of the gate trench at most or all points along the length of the first portion may be substantially similar. The second portion of the gate trench may be a shape having varying width along its length. For example, a width of the gate trench at a first point along the length of the gate trench may be different than a width of the gate trench at a second point along the length of the gate trench. The width may increase, decrease, or both along the length of the gate trench.

Aspects of the present disclosure provide a number of technical effects and benefits. For instance, the shaped finger trench ends can provide improved contact between the gate fingers and the gate bus, improving the electrical conductivity between the gate fingers and the gate bus. This, for instance, can provide for semiconductor devices having improved characteristics, such as improved robustness, improved fabrication tolerances, improved power handling capabilities, and other improved characteristics.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an clement is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based transistor devices for purposes of illustration and discussion. Those of ordinary skill in the art, using the disclosures provided herein, will appreciate that certain aspects of the present disclosure may be applicable to other transistor devices without deviating from the scope of the present disclosure.

In the drawings and specification, there have been disclosed typical embodiments and, although specific terms are employed, they are used in a generic and descriptive sense only and not for purposes of limitation of the scope set forth in the following claims.

Examples of the present disclosure describe an approach to improve the reliability of a power MOSFET and/or IGBT (e.g., gate-controlled devices). The embodiments described herein may be helpful for increasing reliability of the gate-controlled device by removing a condition of the device structure that can lead to reduced performance of the device. For instance, the approaches described herein may provide gate-controlled devices having an improved connection to the gate finger from the gate bus even when a field insulating layer and/or a gate oxide layer are included in the gate trench housing the gate finger.

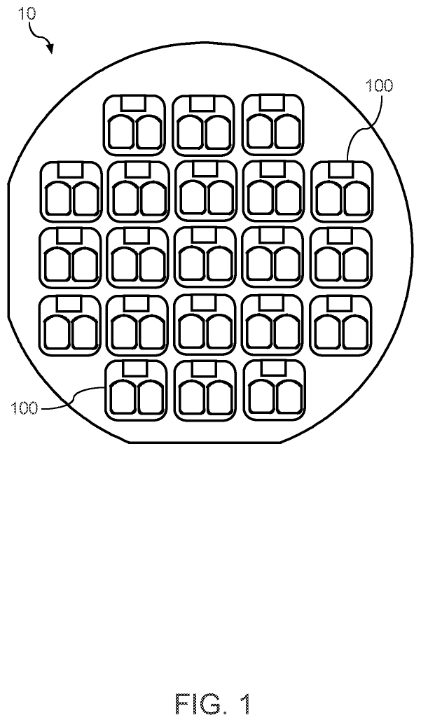

FIG. 1 is a schematic plan view of a wafer 10 that includes a plurality of power semiconductor devices according to embodiments of the present invention. Referring to FIG. 1, the wafer 10 may be a thin planar structure that includes a semiconductor structure with other material layers such as insulating layers and/or metal layers formed thereon. The semiconductor structure may include a semiconductor substrate and/or a plurality of other semiconductor layers. A plurality of power semiconductor devices 100 may be formed in the wafer 10. The semiconductor devices 100 may be formed in rows and columns and may be spaced apart from each other so that the wafer 10 may later be singulated (e.g., diced) to separate the individual semiconductor devices 100 for packaging and testing. The wafer 10 may comprise a silicon carbide substrate having one or more silicon carbide layers formed thereon (e.g., by epitaxial growth) in some embodiments. Other semiconductor layers (e.g., polysilicon layers), insulating layers and/or metal layers may be formed on the silicon carbide semiconductor layer structure to form the power semiconductor devices 100. The silicon carbide substrate and the silicon carbide layers formed thereon may be 4H silicon carbide in some embodiments.

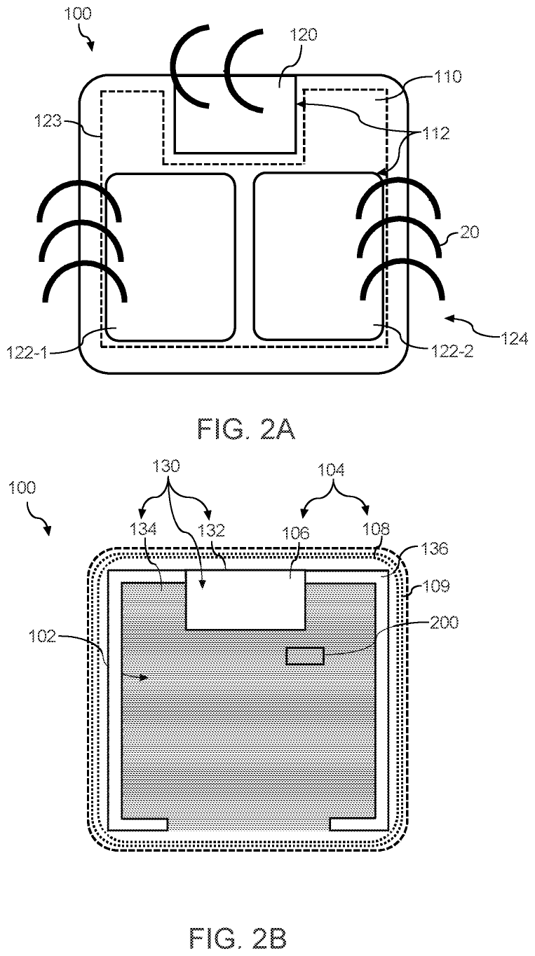

FIG. 2A is a schematic plan view of one of the power semiconductor devices 100 included on the semiconductor wafer 10 of FIG. 1. FIG. 2B is a schematic plan view of the power semiconductor device 100 of FIG. 2A with the source and gate metallization removed. The power semiconductor device 100 may be, for example, a trenched power semiconductor, such as a trench gate MOSFET or IGBT. As shown in FIG. 2A, a protective layer 110 covers a substantial portion of the top surface of the power semiconductor device 100. The protective layer 110 may be formed, for example, of polyamide. Various bond pads may be exposed through openings 112 in the protective layer 110. The bond pads may include a gate bond pad 120 and one or more source bond pads 122. Two source bond pads 122-1, 122-2 are illustrated in FIG. 2A. While not visible in FIG. 2A, a drain bond pad 124 may be provided on the bottom side of the power semiconductor device 100. The bond pads 120, 122, 124 may be formed of a metal, such as aluminum, that bond wires can be readily attached to via conventional techniques such as—thermal compression or soldering. As will be discussed in more detail below, source contacts are provided that contact a semiconductor layer structure of the power semiconductor device 100. The source contacts may be lower portions of a source metal pattern 123 that extends across much of the upper surface of the power semiconductor device 100 (e.g., all but the portion of the upper surface of the power semiconductor device 100 occupied by the gate bond pad 120). The source bond pads 122-1, 122-2 may comprise portions of the source metal pattern 123 that are exposed by the openings 112 in the protective layer 110. Wire bonds 20 are shown in FIG. 2A that may be used to connect the gate bond pad 120 and the source bond pads 122-1, 122-2 to external voltage sources (not shown) such as terminals of other circuit elements.

As is shown in FIG. 2B, the power semiconductor device 100 includes a semiconductor structure that includes an active region 102 and an inactive region 104. The active region 102 is an area of the device that includes operable unit cell structures (e.g., transistors), while the inactive region 104 is an area that does not include such operable unit cell structures. The transistors 200 (e.g., also referred to as “unit cells” or “unit cell transistors”) of the power semiconductor device 100 are formed in the active region 102. The location of one transistor 200 (e.g., a unit cell or unit cell transistor) is shown by a box in FIG. 2B to provide context. The active region 102 may generally correspond to the area under the source metal pattern 123 in some embodiments. The inactive region 104 includes a gate pad portion 106 and a termination portion 108. The gate pad portion 106 of the inactive region 104 may approximately correspond to the portion of the semiconductor layer structure that is underneath the gate pad 120 and the gate buses 136. The termination portion 108 of the inactive region 104 may extend around a periphery of the power semiconductor device 100 and may include one or more termination structures such as guard rings and/or a junction termination extension that can reduce electric field crowding that may occur around the edge of the device. The termination structures (shown as guard rings 109) may spread out the electric fields along the periphery of the power semiconductor device 100, reducing electric field crowding. The termination structures (e.g., termination portion 108 and/or guard rings 109) may serve to increase the reverse blocking voltage at which a phenomenon known as “avalanche breakdown” occurs where an increasing electric field result in runaway generation of charge carriers within the power semiconductor device 100, resulting in a sharp increase in current that may damage or even destroy the device 100. Though guard rings 109 are illustrated in FIG. 2B, it will be understood that these are merely examples, and that other termination structures may be used (e.g., a junction termination extension) or, in some embodiments, omitted without departing from the scope and spirit of the present disclosure.

As is further shown in FIG. 2B, a gate electrode pattern 130 may be provided that includes a gate pad 132, a plurality of gate fingers 134, and one or more gate buses 136 that electrically connect the gate fingers 134 to the gate pad 132. The gate pad 132 portion of the gate electrode pattern 130 may be underneath the gate bond pad 120 in the gate pad portion 106 of the inactive region 104, and the gate fingers 134 may extend horizontally across the active region 102. An insulating layer (not shown) may cover the gate fingers 134 and gate bus(es) 136. The source metal pattern 123 may be provided over the gate fingers 134 and insulating layer, with the source contacts of the source metal layer contacting corresponding source regions in the semiconductor layer structure in openings between the gate fingers 134. The gate fingers 134 may be implemented in a trench configuration, in which at least a portion of the gate finger 134 extends below an upper surface of the semiconductor layer structure in a gate trench.

The gate fingers 134 may distribute a gate signal of the power semiconductor device 100 throughout the active region 102. In some embodiments, gate fingers 134 (and/or gate trenches) of a gate electrode may have a longitudinal axis that extends in a common direction (e.g., the horizontal direction in FIG. 2B). However, the gate fingers 134 may be in other patterns without deviating from the scope of the present disclosure.

In some embodiments, the gate fingers 134 may include a conductive material (e.g., polysilicon and/or a silicide). In some implementations, the gate buses 136 may have a lower resistivity than the gate fingers 134. For instance, in some implementations, the gate bus(es) 136 may be or may contain metal, and the gate fingers 134 may be or may contain silicon (Si), polysilicon, silicide, or other suitable materials.

FIG. 2C is a schematic cross-sectional diagram that illustrates an example unit cell structure in an active region of the device. It will be appreciated that the specific layer structure, doping concentrations, materials, conductivity types and the like that are shown in FIG. 2C and/or described below are merely provided as examples to illustrate in detail the structure of a specific example embodiment. Thus, the specific details discussed below are not intended to be limiting to the present disclosure.

Referring to FIG. 2C, the unit cell 200 is part of the active region 102 of the power semiconductor device 100. The unit cell 200 may be one of a plurality of unit cells 200 that are electrically disposed in parallel. It will be appreciated that FIG. 2C illustrates one full unit cell 200 and portions of two additional unit cells 200 on either side thereof in order to provide context.

As shown in FIG. 2C, the power semiconductor device 100, and hence the unit cell 200, includes an n-type wide band-gap semiconductor substrate 210. The substrate 210 may include, for example, a single crystal 4H silicon carbide semiconductor substrate. The substrate 210 may be heavily-doped with n-type impurities (i.e., an n+ silicon carbide substrate). The impurities may comprise, for example, nitrogen or phosphorus. The doping concentration of the substrate 210 may be, for example, between 1×10¹⁸ atoms/cm³ and 1×10²¹ atoms/cm³, although other doping concentrations may be used. The substrate 210 may be any appropriate thickness (e.g., between about 0 (in the case of the drift layer being on metal) and about 800 microns thick).

A lightly-doped n-type (n) silicon carbide drift region 220 is provided on the substrate 210. The n-type silicon carbide drift region 220 may be formed by, for example, epitaxial growth on the silicon carbide substrate 210. The n-type silicon carbide drift region 220 may have, for example, a doping concentration of 1×10¹⁴ to 5×10¹⁷ dopants/cm³. The n-type silicon carbide drift region 220 may be a thick region, having a vertical height above the substrate 210 of, for example, about 3-100 microns. An upper portion of the n-type silicon carbide drift region 220 may comprise an n-type silicon carbide current spreading layer in some embodiments. The n-type silicon carbide current spreading layer may be grown in the same processing step as the remainder of the n-type silicon carbide drift region 220 and may be considered to be part of the n-type silicon carbide drift region 220. The n-type current spreading layer may be a moderately-doped current spreading layer that has a doping concentration (e.g., doping concentration of 1×10¹⁶ to 5×10¹⁸ dopants/cm³) that exceeds the doping concentration of the remainder of the more lightly-doped n-type silicon carbide drift layer 220. The n-type current spreading layer may be omitted in some embodiments.

An upper portion of the n-type drift region 220 may be doped p-type by ion implantation to form p-wells 240. The p-wells 240 may have a doping concentration of, for example, between 5×10¹⁶/cm³ and 5×10¹⁹/cm³. An upper portion 242 of each p-well may be more heavily doped with p-type dopants. The upper portion 242 of each p-well 240 may have a doping concentration of, for example, between 2×10¹⁸/cm³ and 1×10²⁰/cm³. The p-wells 240 (including the more heavily-doped upper portions 242 thereof) may be formed by ion implantation. Ions such as n-type or p-type dopants may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may extend into the semiconductor layer to a certain depth.

Heavily-doped (n+) n-type silicon carbide source regions 250 may be formed in upper portions of the p-wells 240 directly adjacent and contacting the more heavily doped portions 242 of the p-wells 240. The n-type source regions 250 may also be formed by ion implantation and/or using epitaxial growth. The heavily-doped (n+) n-type silicon carbide regions 250 act as source regions for the unit cell transistor. The drift region 220 and the substrate 210 together act as a common drain region for the power semiconductor device 100.

The n-type silicon carbide substrate 210, n-type silicon carbide drift region 220, the p-wells 240, 242 and the n-type source regions 250 formed therein may together comprise a semiconductor structure of the semiconductor device 100.

Gate trenches 275 may be formed in the semiconductor structure. A gate oxide layer 260 may be formed in gate trenches 275. The gate oxide layer 260 may include, for example, a silicon oxide layer, although other insulating materials may be used. A gate finger 134 is on the gate oxide layer 260 in the gate trench 275. Accordingly, it will be appreciated that the gate finger 134 may be part of a continuous gate structure that includes the gate pad 132, one or more gate buses 136, and a plurality of gate fingers 134.

Source contacts 280 may be on the heavily-doped n-type source regions 250 and the more heavily-doped portions 242 of the p-wells. As described above with reference to FIGS. 2A-2B, the source contacts 280 may be part of a continuous source pattern 123 that extends across the upper surface of the silicon carbide semiconductor layer structure. The remainder of the source pattern 123 (as well as the insulating layer that electrically isolates the gate fingers 270 from the source pattern 123) is not shown in FIG. 2C to simplify the drawings. The source contacts 280 may include, for example, metals such as nickel, titanium, tungsten or aluminum, or alloys or thin layered stacks of these or similar materials. As described above, a drain contact 124 may be on the lower surface of the substrate 210. The drain contact 124 may include, for example, similar materials to the source contact, as this forms an ohmic contact to the silicon carbide substrate. While the power semiconductor device 100 is an n-type device with the source contacts 280 on an upper surface thereof and the drain contact 124 on the bottom surface thereof, it will be appreciated that in p-type devices these locations are reversed.

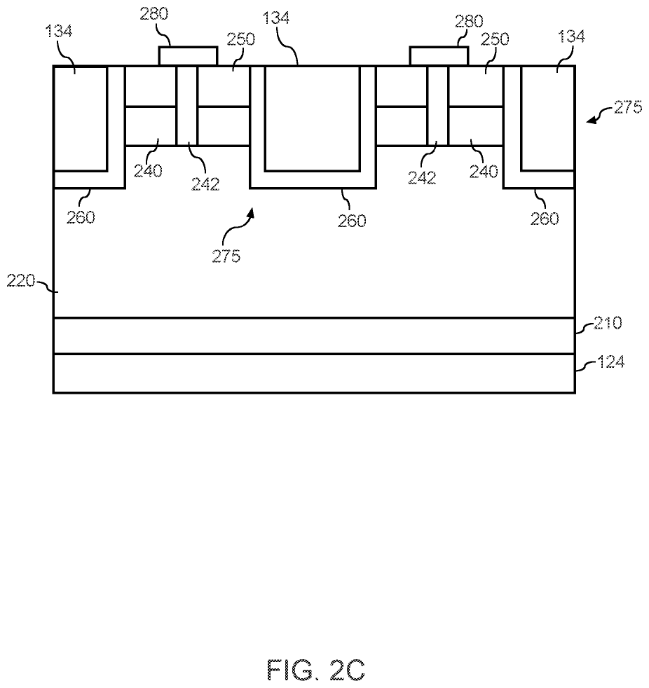

FIG. 3 depicts a view of a portion of an example gate trench 300 according to example embodiments of the present disclosure. For instance, the gate trench 300 may be disposed in a semiconductor structure, such as a power semiconductor device (e.g., the power semiconductor device 100 of FIGS. 1 and 2A-2C). The gate trench 300 may correspond to the gate trench 275 depicted in FIG. 2C.

A gate finger (e.g., gate finger 134) can be in the gate trench 300. For instance, the gate finger may be formed, deposited, extruded, or otherwise arranged in the gate trench 300. As one example, the gate trench 300 can house one of the gate fingers 134 of FIG. 2B and 2C. In some examples, the shape of the gate finger may generally conform to that of the gate trench 300.

For the purposes of illustration herein, the terms gate finger and gate trench may be used interchangeably in some contexts to describe the arrangement of elements. For instance, a component extending opposite to a gate finger can equally extend opposite to a gate trench. It should be understood that, when a distinction is required, a gate finger refers to a structure formed of conductive material (e.g., polycrystalline silicon (Si)) and a gate trench refers to the cavity formed in the underlying material (e.g., a semiconductor structure) to hold the gate finger.

The gate trench 300 can extend a length in a semiconductor structure. For instance, the gate trench 300 may extend from an intersection with a gate bus. The gate trench 300 may extend between any other two points on a semiconductor device. According to example aspects of the present disclosure, the gate trench 300 can include a first portion 302 and a second portion 304. The first portion 302 can have a first width (W₁). The second portion 304 can have a second width (W₂). The second width (W₂) can be different than the first width (W₁). For instance, in the example gate trench 300 of FIG. 3, the second width (W₂) can be greater than the first width. In some embodiments, the first width (W₁) of the first portion 302 may be relatively narrow for improving and/or optimizing the device properties. For example, in some embodiments, the first width (W₁) may be in a range of about 0.3 μm to about 0.8 μm. In some embodiments, the second width (W₂) of the second portion 304 may be greater than the first width (W₁) so as to have a better contact area with a gate bus and to accommodate structures in the gate trench proximate a gate bus, such as a thick field insulating layer.

In addition, the first portion 302 can have a first length (L₁). The second portion 304 can have a second length (L₂). The first length (L₁) can be greater than the second length (L₂), such as significantly greater than the second length. For instance, in some implementations, the first length (L₁) can be at least 10 times greater than the second length (L₂). The first portion 302 can be configured to extend through the active region of a semiconductor device.

As will be discussed in detail below, the second portion 304 can be positioned at an inactive region of the semiconductor device, such as an intersection between the gate trench 300 and a gate bus. The gate bus can overlap at least a portion of a gate finger in the second portion 304 of the gate trench 300. For instance, returning to the example of FIG. 2B, the second portion 304 of the gate trench 300 can occur at the intersections between the gate finger(s) 134 and the gate bus(s) 136.

FIG. 3 depicts one portion of the gate trench 300 for purposes of illustration and discussion. It should be understood that, in some embodiments, another end of the gate trench 300 not depicted in FIG. 3 (e.g., continuing along the length of first portion 302 in a direction opposite the second portion 304) may include another portion having a different width, such as the second width or another different width. In some embodiments, the first portion 302 can continue until termination of the gate trench 300.

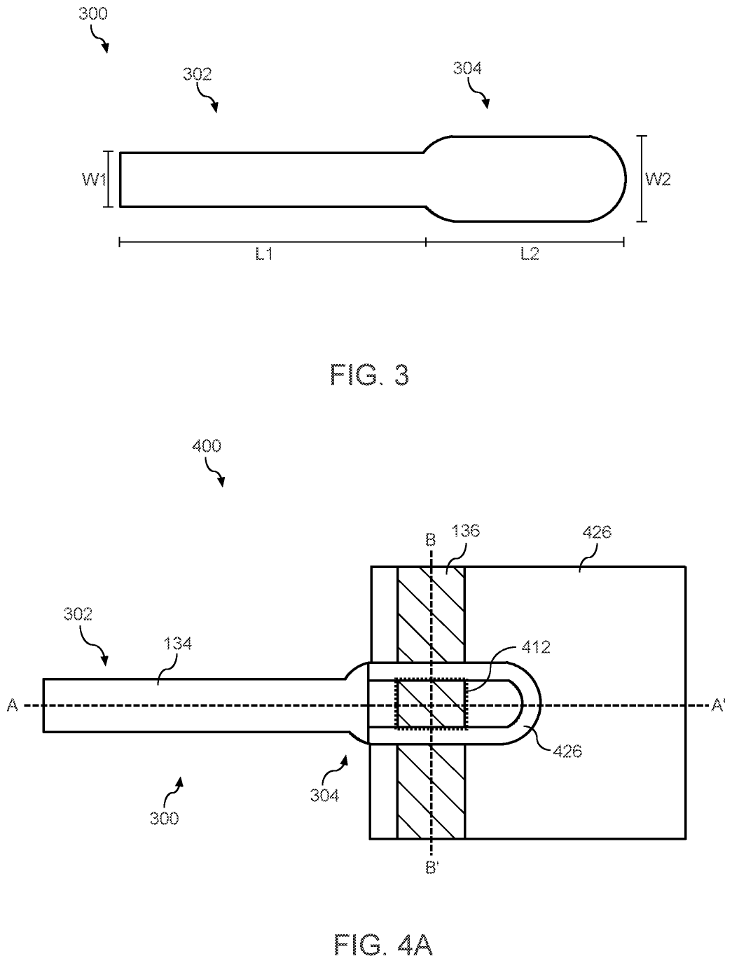

FIG. 4A depicts a plan view of a portion of an example intersection 400 between a gate finger 134 (e.g., in gate trench 300) and a gate bus 136 according to example embodiments of the present disclosure. For instance, the intersection 400 may be a portion of a gate electrode structure 130 for a semiconductor device, including a gate pad 132, a plurality of gate fingers 134, and one or more gate buses 136 that electrically connect the gate fingers 134 to the gate pad 132 as shown in FIGS. 2A-2C. The gate bus 136 can overlap at least a portion of the gate finger 134 in the second portion 304 of the gate trench 300. The gate bus 136 may therefore be operable to conductively communicate a gate signal to the gate fingers 134.

The gate finger 134 may extend (e.g., horizontally) across an active region of the semiconductor device. In addition, the gate bus 136 may extend in an inactive region of the semiconductor device. In some implementations, the gate finger 134 and the gate bus 136 can extend in different directions.

According to example aspects of the present disclosure, a thick field insulating layer 426 and/or a gate oxide layer 428 (FIGS. 4B-4C) may be in the inactive region and in the second portion 304 of the gate trench 300. The gate finger 136 of the gate trench 300 can be coupled (e.g., directly coupled) to the gate bus 136 at coupling region 412. The gate finger 134 can be in direct contact with the gate bus 136 at a location (e.g., the coupling region 412) overlapping or in the second portion 304 of the gate trench 300. For instance, the coupling region 412 can be an exposed region without any intervening layers or elements that provides for electrical conductivity between the gate bus 136 and the gate finger 134 in the second portion of the gate trench 300. As an example, the gate bus 136 may be directly on the gate finger 134 in the second portion 304 of the gate trench 300 without a break in conductive material between the gate finger 134 and the gate bus 136. The gate bus 136 at least partially overlaps the second portion 304 of the gate trench 300.

FIG. 4B depicts a cross-sectional view of the example intersection 400 of FIG. 4A along the line A-A′ according to example embodiments of the present disclosure. FIG. 4B depicts the substrate 210, drift region 220, and well region 240 of the semiconductor structure in the inactive region. The inactive region shown in FIG. 4B may further include a highly doped p-type p+ region 425. FIG. 4B further illustrates a p-type doped shield region 422 that, in some examples, is present in an inactive region of the semiconductor device. The p-type shield region 422 can protect portions of the gate oxide layer 428 and the field insulating layer 426 from high electric fields, which may otherwise degrade the gate oxide layer 428 and the field insulating layer 426.

The intersection 400 illustrates the field insulating layer 426 and the gate oxide layer 428 on the semiconductor structure. The field insulating layer 426 can be or can include, for example, a SiOx layer. The gate oxide layer 428 can be or can include, for example, a SiOx layer. A thickness of the field insulating layer 426 can be greater than a thickness of the gate oxide layer 428. For instance, in some implementations, the field insulating layer 426 may have a thickness between about 0.3 microns to about 0.5 microns, although other thicknesses may be used without deviating from the scope of the present disclosure. The gate oxide layer 428 may have a thickness between about 50 nm to about 100 nm.

According to example aspects of the present disclosure, the field insulating layer 426 can be in the second portion 304 of the gate trench 300. The gate oxide layer 428 can be within the gate trench 300 (e.g., the first portion 302 and the second portion 304) of the gate trench 300. For instance, the gate oxide layer can be between the field insulating layer 426 and the gate bus 136 in the second portion 304 of the gate trench 300.

FIG. 4C depicts a cross-sectional view of the example intersection 400 of FIG. 4A along the line B-B′ according to example embodiments of the present disclosure. FIG. 4C illustrates a bottom surface of the gate trench 405 and sidewalls 434 of the second portion 304 of gate trench 300. As illustrated, the gate oxide layer 428 and the field insulating layer 426 can be between the gate finger 136 and the semiconductor structure on the bottom surface 432 of the gate trench 300 and at the sidewalls 434 of the gate trench 300.

In some implementations, the field insulating layer 426 can have a first thickness on the bottom surface 432 of the second portion 304 of the gate trench 300 and a second thickness on the sidewalls 434 of the second portion 304 of the gate trench 300. The first thickness can be different than the second thickness. For instance, as illustrated in FIG. 4C, the first thickness can be greater than the second thickness.

In some implementations, the gate oxide layer 428 can be between the gate finger 136 and a bottom surface 432 of the gate trench 300. For instance, as shown in FIG. 4B, the bottom surface 432 of the gate trench 300 can include a first portion 302 that extends along the direction of the gate trench 300 and a second portion 304 that vertically overlaps with the gate bus 136. In some examples, a first portion of the gate oxide layer 428 can be between the gate finger 134 of the gate trench 300 and the semiconductor structure in the first portion 302 of the gate trench 300. For instance, the first portion 302 of the gate trench 300 may include only the gate oxide layer 428 and not the field insulating layer 426. In some implementations, a second portion of the gate oxide layer 428 can be between the field insulating layer 426 and the gate finger 134 in the second portion 304 of the gate trench 300. For instance, the field insulating layer 426 fills at least a part of the second portion 304 of the gate trench 300.

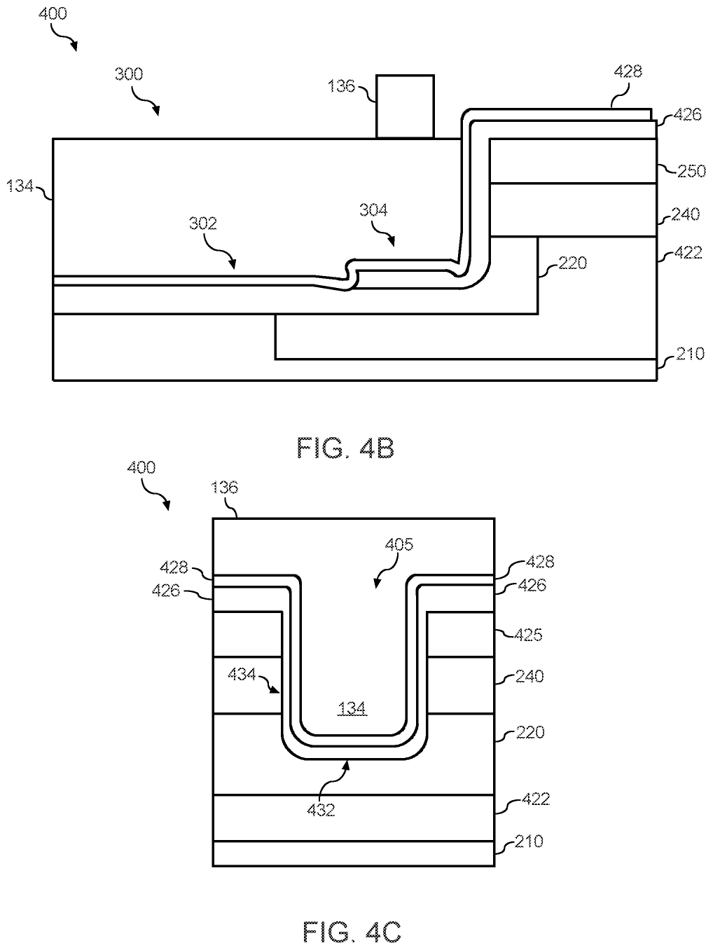

The second portion of the gate trench in the portion where the gate bus 136 at least partially overlaps the gate finger 134 may have other shapes without deviating from the scope of the present disclosure. For instance, FIG. 5 depicts a view of a plan portion of an example gate trench 500 according to example embodiments of the present disclosure. In this example, the gate trench 500 can include a first portion 502 and a second portion 504. The first portion 502 can have a first width (W₁). The second portion 504 can have a second width (W₂). The second width (W₂) can be different than the first width. For instance, in the example gate trench 500, the second width (W₂) can be less than the first width.

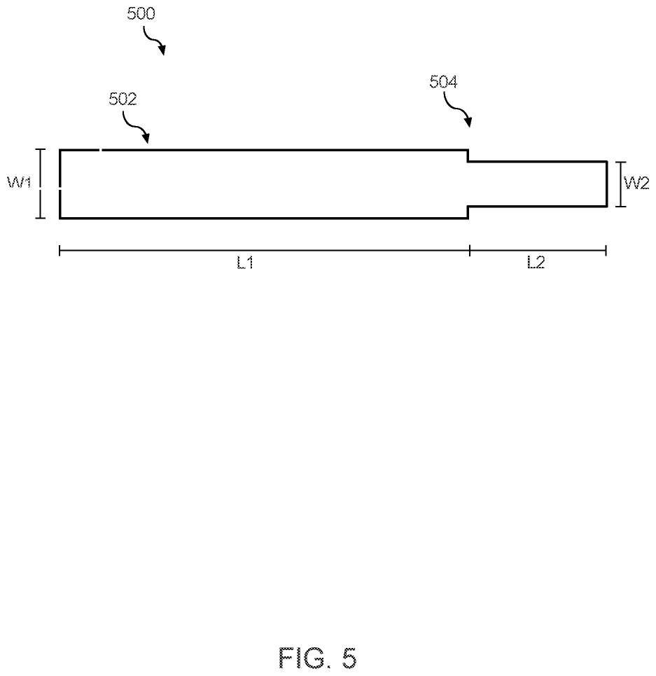

As another example, FIG. 6 depicts example adjacent gate trenches where a second portion of the gate trench is contiguous with an adjacent gate trench according to example embodiments of the present disclosure. For instance, FIG. 6 depicts a first gate trench 610 having a first portion 612 and a second portion 614, a second gate trench 620 having a first portion 622 and a second portion 624, and a third gate trench 630 having a first portion 632 and a second portion 634. The second portion 614 of the first gate trench 610 may be contiguous with the second portion 624 of the second gate trench 620. The second portion 624 of the second gate trench 620 may be contiguous with the second portion 634 of the third gate trench 630. In some examples, the gate fingers in the gate trenches 610, 620, 630 are contiguous. For instance, the gate finger in the first gate trench 610 may be contiguous (e.g., in contact with) the gate finger in the second gate trench 620 at the border 615 between the second portion 614 of the first gate trench 610 and the second portion 624 of the second gate trench 620. Similarly, the gate finger in the second gate trench 620 may be contiguous (e.g., in contact with) the gate finger in the third gate trench 630 at the border 625 between the second portion 624 of the second gate trench 620 and the second portion 634 of the third gate trench 630.

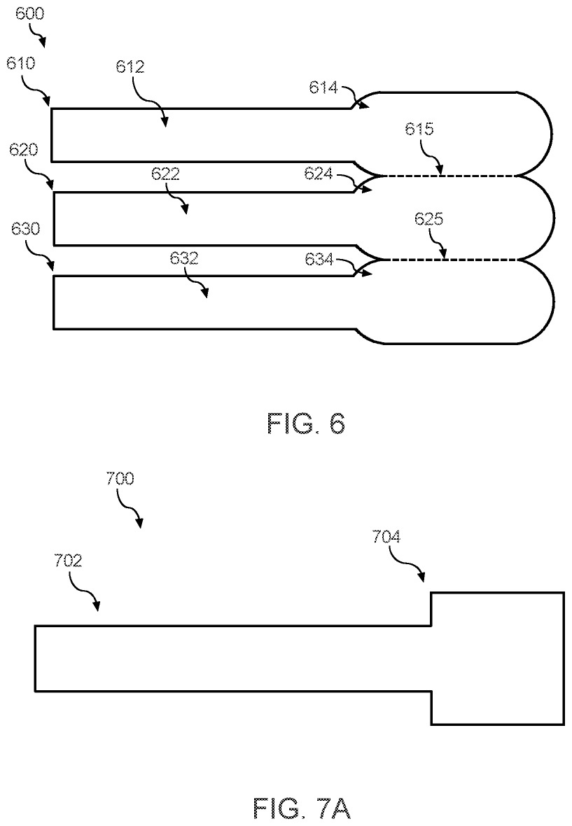

FIGS. 7A-7C depict example gate trenches according to example embodiments of the present disclosure. In particular, FIGS. 7A-7C depict gate trenches where the second portion of the gate trench has a different shape relative to the first portion of the gate trench. As an example, the first portion of the gate trench may be a shape having generally constant width along its length. For instance, the width of the gate trench at most or all points along the length of the first portion may be substantially similar. The second portion of the gate trench may be a shape having varying width along its length. For example, a width of the gate trench at a first point along the length of the gate trench may be different (e.g., more than about 10% different) than a width of the gate trench at a second point along the length of the gate trench. The width may increase, decrease, or both along the length of the gate trench.

For instance, FIG. 7A depicts a gate trench 700 having a first portion 702 and a second portion 704. The first portion 702 generally resembles a line. In addition, the second portion 704, viewed from “top-down” (e.g., looking into the gate trench 700), resembles a square. Similarly, FIG. 7B depicts a gate trench 720 having a first portion 712 and a second portion 714 that is generally circular. Furthermore, FIG. 7C depicts a gate trench 720 having a first portion 722 and a second portion 724 that is generally triangular. As used herein, it should be understood that comparisons to geometric shapes are for the purposes of illustration only, and the shape of the second portions of gate trenches does not necessarily have to resemble a regular geometric shape and could, in some examples, be an irregular geometric shape.

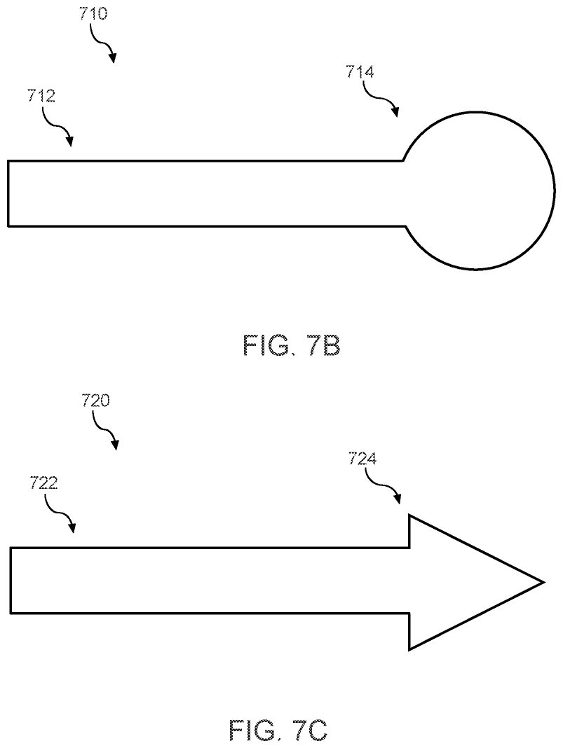

FIG. 8 depicts a cross-sectional view of an example intersection 800 between a gate finger and a gate bus according to example embodiments of the present disclosure. The intersection 800 may be similar to the intersection 400 of FIG. 4C. For instance, the components of FIG. 8 may be similar to their counterparts described in FIG. 4C, except where otherwise indicated. For example, as illustrated, the intersection 800 may include a gate trench 805, a gate bus 815, and a semiconductor structure 820 including, for example, a substrate 821, a shield region 822, a drift region 823, and a well region 824. The semiconductor structure 820 may further include a highly doped p-type p+ region 825. A field insulating layer 826 and a gate oxide layer 828 can be on or in the gate trench 805. The field insulating layer 826 can have a first thickness on the bottom surface 832 of the gate trench 805 and a second thickness on the sidewalls 834 of the gate trench 805. The first thickness can be different than the second thickness. In the example of FIG. 8, the first thickness is less than the second thickness.

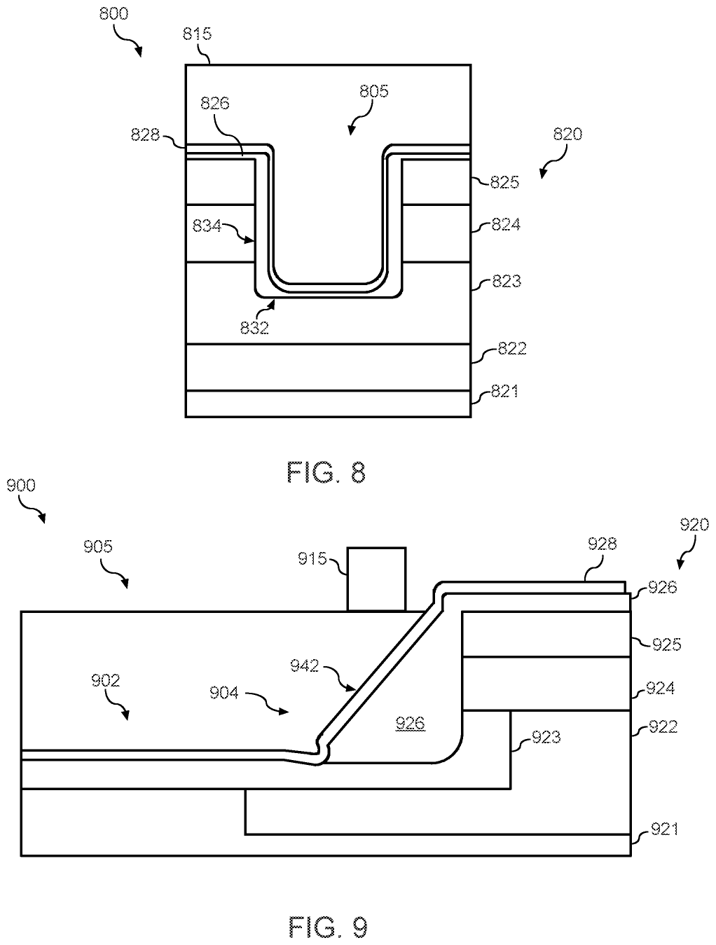

FIG. 9 depicts a cross-sectional view of an example intersection 900 between a gate finger and a gate bus according to example embodiments of the present disclosure. The intersection 900 may be similar to the intersection 400 of FIG. 4B. For instance, the components of FIG. 9 may be similar to their counterparts described in FIG. 4B, except where otherwise indicated. For example, as illustrated, the intersection 900 may include a gate trench 905 having a first portion 902 and a second portion 904, a gate bus 915, and a semiconductor structure 920 including, for example, a substrate 921, a shield pattern 922, a drift region 923, and a well region 924. The semiconductor structure 920 may further include a highly doped p-type p+ region 925. A field insulating layer 926 and a gate oxide layer 928 can be on or in the gate trench 905.

In the example of FIG. 9, however, the field insulating layer 926 can have a sloped surface profile 942 extending along the length of the gate trench 905. For instance, the sloped surface profile 942 can extend along the length of the second portion 904 of the gate trench 905. While a linear sloped surface profile is illustrated in FIG. 9, it should be understood that the sloped surface profile can have any suitable profile, such as, for example, a “stair” profile, a concave or convex profile, or any other suitable profile.

One example aspect of the present disclosure is directed to a semiconductor device. The semiconductor device includes a semiconductor structure. The semiconductor device includes a gate finger in a gate trench in the semiconductor structure. The gate trench extends a length in the semiconductor structure. The gate trench has a first portion having a first width and a second portion having a second width. The second width is different than the first width.

In some examples, the second width is greater than the first width.

In some examples, the second width is less than the first width.

In some examples, the second portion has a different shape relative to the first portion.

In some examples, the first portion has a first length, the second portion has a second length, wherein the first length is at least 10 times greater than the second length.

In some examples, the second portion of the gate trench is contiguous with an adjacent gate trench.

In some examples, the semiconductor device further comprises a gate bus, wherein the gate bus overlaps at least a portion of the gate finger in the second portion of the gate trench.

In some examples, the gate finger and the gate bus extend in different directions.

In some examples, the semiconductor device comprises a field insulating layer between the gate bus and the semiconductor structure.

In some examples, the field insulating layer has a thickness in a range of about 0.3 microns to about to about 0.5 microns.

In some examples, the semiconductor device comprises a gate oxide layer between the field insulating layer and the gate bus.

In some examples, the gate oxide layer has a thickness of about 50 nm to about 100 nm.

In some examples, the gate oxide layer is between the gate finger and a bottom of the gate trench.

In some examples, the field insulating layer is in the second portion of the gate trench.

In some examples, the field insulating layer has a first thickness on a bottom surface of the gate trench and a second thickness on a sidewall of the gate trench.

In some examples, the first thickness is different than the second thickness.

In some examples, the first thickness is greater than the second thickness.

In some examples, the first thickness is less than the second thickness.

In some examples, the field insulating layer fills at least a part of the second portion of the gate trench.

In some examples, the field insulating layer has a sloped surface profile extending along the length of the gate trench in the second portion.

In some examples, the semiconductor structure is a wide bandgap semiconductor structure.

In some examples, the wide bandgap semiconductor structure comprises a drift region of a first conductivity type and a well region of a second conductivity type.

In some examples, the wide bandgap semiconductor structure comprises silicon carbide.

In some examples, the semiconductor device is a MOSFET.

Another example aspect of the present disclosure is directed to a semiconductor device. The semiconductor device includes a semiconductor structure comprising an active region and an inactive region. The semiconductor device includes a gate bus on the inactive region. The semiconductor device includes a gate trench having a first portion in the active region and a second portion in the inactive region. The semiconductor device includes a gate finger extending in the active region in the first portion of the gate trench. The semiconductor device includes a field insulating layer on the inactive region and in the second portion of the gate trench.

In some examples, the field insulating layer has a thickness of about 0.3 microns to about 0.5 microns.

In some examples, the semiconductor device comprises a gate oxide layer.

In some examples, a first portion of the gate oxide layer is between the gate finger and the semiconductor structure in the first portion of the gate trench, wherein a second portion of the gate oxide layer is between the field insulating layer and the gate finger in the second portion of the gate trench.

In some examples, the field insulating layer in the second portion of the gate trench has a first thickness on a bottom surface of the gate trench and a second thickness on a sidewall of the gate trench, wherein the first thickness is different than the second thickness.

In some examples, the field insulating layer has a sloped surface profile extending along a length of the gate trench in the second portion.

In some examples, the first portion of the gate trench has a first width and the second portion of the gate trench has a second width.

In some examples, the second width is greater than the first width.

In some examples, the second width is less than the first width.

In some examples, the second portion of the gate trench has a different shape relative to the first portion of the gate trench.

In some examples, the first portion has a first length, the second portion has a second length, wherein the first length is at least 10 times greater than the second length.

In some examples, the second portion of the gate trench is contiguous with an adjacent gate trench.

In some examples, the semiconductor structure is a wide bandgap semiconductor structure.

In some examples, the wide bandgap semiconductor structure comprises a drift region of a first conductivity type and a well region of a second conductivity type.

In some examples, the wide bandgap semiconductor structure comprises silicon carbide.

In some examples, the semiconductor device is a MOSFET.

Another example aspect of the present disclosure is directed to a semiconductor device. The semiconductor device includes a wide bandgap semiconductor structure having an active region and an inactive region. The active region has one or more unit cells. The semiconductor device includes a gate bus. The semiconductor device includes a gate trench in the wide bandgap semiconductor structure. The gate trench has a first portion and a second portion. The semiconductor device includes a gate finger in the gate trench. The semiconductor device includes a field insulating layer in the second portion of the gate trench. The gate finger overlaps the gate bus at the second portion of the gate trench. The first portion of the gate trench has a first width and the second portion of the gate trench has a second width. The second width is different than the first width.

In some examples, the field insulating layer is not in the first portion of the gate trench.

In some examples, the semiconductor device comprises a gate oxide layer.

In some examples, the gate oxide layer is between the field insulating layer and the gate finger in the second portion of the gate trench.

In some examples, the gate oxide layer is between the gate finger and the wide bandgap semiconductor structure in the first portion of the gate trench.

In some examples, the field insulating layer has a thickness of about 0.3 microns to about 0.5 microns.

In some examples, the field insulating layer in the second portion of the gate trench has a first thickness on a bottom surface of the gate trench and a second thickness on a sidewall of the gate trench, wherein the first thickness is different than the second thickness.

In some examples, the field insulating layer has a sloped surface profile extending along a length of the gate trench in the second portion.

In some examples, the second width is greater than the first width.

In some examples, the second width is less than the first width.

In some examples, the second portion of the gate trench has a different shape relative to the first portion of the gate trench.

In some examples, the first portion has a first length, the second portion has a second length, wherein the first length is at least 10 times greater than the second length.

In some examples, the second portion of the gate trench is contiguous with a second portion of an adjacent gate trench.

In some examples, the wide bandgap semiconductor structure comprises a drift region of a first conductivity type and a well region of a second conductivity type.

In some examples, the wide bandgap semiconductor structure comprises silicon carbide.

In some examples, the semiconductor device is a MOSFET.

In some examples, the gate bus overlaps the inactive region of the wide bandgap semiconductor structure.

In some examples, the first portion of the gate trench is in the active region.

In some examples, the second portion of the gate trench is in the inactive region.

In some examples, the gate finger is in direct contact with the gate bus at a location overlapping the second portion of the gate trench.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device, comprising:
a semiconductor structure;
a gate finger in a gate trench in the semiconductor structure; and
wherein the gate trench extends a length in the semiconductor structure, the gate trench having a first portion having a first width and a second portion having a second width, wherein the second width is different than the first width.

2. The semiconductor device of claim 1, wherein the second width is greater than the first width.

3. The semiconductor device of claim 1, wherein the second width is less than the first width.

4. The semiconductor device of claim 1, wherein the second portion has a different shape relative to the first portion.

5. The semiconductor device of claim 1, wherein the first portion has a first length, the second portion has a second length, wherein the first length is at least 10 times greater than the second length.

6. The semiconductor device of claim 1, wherein the second portion of the gate trench is contiguous with an adjacent gate trench.

7. The semiconductor device of claim 1, wherein the semiconductor device further comprises a gate bus, wherein the gate bus overlaps at least a portion of the gate finger in the second portion of the gate trench.

8. The semiconductor device of claim 7, wherein the gate finger and the gate bus extend in different directions.

9. The semiconductor device of claim 7, further comprising a field insulating layer between the gate bus and the semiconductor structure.

10. The semiconductor device of claim 9, wherein the field insulating layer has a thickness in a range of about 0.3 microns to about to about 0.5 microns.

11. The semiconductor device of claim 10, further comprising a gate oxide layer between the field insulating layer and the gate bus.

12. The semiconductor device of claim 11, wherein the gate oxide layer has a thickness of about 50 nm to about 100 nm.

13. (canceled)

14. The semiconductor device of claim 9, wherein the field insulating layer is in the second portion of the gate trench.

15. The semiconductor device of claim 14, wherein the field insulating layer has a first thickness on a bottom surface of the gate trench and a second thickness on a sidewall of the gate trench, the first thickness being different than the second thickness.

16.-19. (canceled)

20. The semiconductor device of claim 9, wherein the field insulating layer has a sloped surface profile extending along the length of the gate trench in the second portion.

21. The semiconductor device of claim 1, wherein the semiconductor structure is a wide bandgap semiconductor structure.

22. (canceled)

23. The semiconductor device of claim 21, wherein the wide bandgap semiconductor structure comprises silicon carbide.

24. The semiconductor device of claim 1, wherein the semiconductor device is a MOSFET.

25. A semiconductor device, comprising:
a semiconductor structure comprising an active region and an inactive region;
a gate bus on the inactive region;
a gate trench having a first portion in the active region and a second portion in the inactive region;
a gate finger extending in the active region in the first portion of the gate trench; and
a field insulating layer on the inactive region and in the second portion of the gate trench.

26.-40. (canceled)

41. A semiconductor device, comprising:
a wide bandgap semiconductor structure having an active region and an inactive region, the active region having one or more unit cell structures;
a gate bus;
a gate trench in the wide bandgap semiconductor structure, the gate trench having a first portion and a second portion;
a gate finger in the gate trench;
a field insulating layer in the second portion of the gate trench;
wherein the gate finger overlaps the gate bus at the second portion of the gate trench; and
wherein the first portion of the gate trench has a first width and the second portion of the gate trench has a second width, wherein the second width is different than the first width.

42.-60. (canceled)
